(19) United States
(12) Patent Application Publication
(10) Pub. No.: US 2024/0389306 A1
(43) Pub. Date: Nov. 21, 2024

(54) SEMICONDUCTOR DEVICE AND MANUFACTURING METHOD THEREFOR, AND DYNAMIC RANDOM ACCESS MEMORY AND ELECTRONIC DEVICE

(71) Applicant: BEIJING SUPERSTRING ACADEMY OF MEMORY TECHNOLOGY, Beijing (CN)

(72) Inventors: Xiangsheng Wang, Beijing (CN); Guilei Wang, Beijing (CN); Chao Zhao, Beijing (CN)

(73) Assignee: BEIJING SUPERSTRING ACADEMY OF MEMORY TECHNOLOGY, Beijing (CN)

(21) Appl. No.: 18/691,823

(22) PCT Filed: Sep. 23, 2022
(86) PCT No.: PCT/CN2022/120903

§ 371 Date: Mar. 13, 2024

(30) Foreign Application Priority Data
May 17, 2022 (CN) 202210542082.7

(51) Int. Cl. H10B 12/00

(52) U.S. Cl. CPC H10B 12/482; H10B 12/033; H10B 12/31; H10B 12/485; H10B 12/488

(57) ABSTRACT

The semiconductor device includes: a substrate; a plurality of memory cell columns, wherein each memory cell column includes a plurality of memory cells, arranged and stacked on one side of the substrate in a first direction, and the plurality of memory cell columns are arranged on the substrate in a second direction and in a third direction to form an array; the memory cells each include a transistor and a capacitor, the transistor including a semiconductor layer and a gate, and semiconductor layer includes a source region, an inversion channel region and a drain region; a plurality of bit lines, extending in the first direction, wherein the source regions of the transistors of the plurality of memory cells in two adjacent memory cell columns in the second direction, are all connected to one bit line; and a plurality of word lines, extending in the third direction.

### CROSS-REFERENCE TO RELATED APPLICATIONS

The present application is a U.S. National Phase Entry of International Application PCT/CN2022/120903 having an international filing date of Sep. 23, 2022, which claims priority to Chinese Patent Application No. 202210542082.7 filed to the CNIPA on May 17, 2022 and entitled “Semiconductor Device Structure and Manufacturing Method Thereof, DRAM and Electronic Device”, and the contents disclosed in the above-mentioned applications are incorporated into the present disclosure by reference.

### TECHNICAL FIELD

The present disclosure relates to, but is not limited to, the field of semiconductor devices, in particular to a semiconductor device and manufacturing method thereof, a dynamic random access memory and an electronic device.

### BACKGROUND

Dynamic Random Access Memory (DRAM) is widely used in personal computers, notebooks and consumer electronics products. In order to rapidly improve the integration and scalability of memory, the feature size of semiconductor devices is shrinking. It becomes more and more difficult for the scaling down of its capacitor area, the preparation process is becoming more and more complex.

### SUMMARY

The following is a summary of the subject matters described in detail in this document. This summary is not intended to limit the scope of protection of the present disclosure.

An embodiment of the present disclosure provides a semiconductor device, including:
a substrate;
a plurality of memory cell columns, wherein each of the memory cell columns includes a plurality of memory cells disposed and stacked along a first direction on a side of the substrate, and the plurality of memory cell columns are arranged to be an array on the substrate along a second direction and a third direction; the memory cell includes a transistor and a capacitor, wherein the transistor includes a semiconductor layer and a gate; the semiconductor layer extends along the second direction and includes a source region, a channel region and a drain region, wherein the source region and the drain region are respectively located at two ends of the semiconductor layer, the channel region is located between the source region and the drain region, and the gate surrounds the channel region; the capacitor surrounds an end of the drain region away from the channel region, and the channel region of the semiconductor layer is an inversion channel region;
a plurality of bit lines extending along the first direction, wherein source regions of transistors of a plurality of memory cells of two adjacent memory cell columns along the second direction are all connected to one common bit line;
a plurality of word lines extending along a third direction, wherein the substrate is provided with one memory cell column in the third direction, and each of the word lines is formed by a gate of a transistor of one memory cell of one memory cell column arranged along the third direction; or the substrate is provided with a plurality of memory cell columns in the third direction, and each of the word lines is formed by connecting together gates of transistors of the plurality of memory cells arranged along the third direction.

In an embodiment of the present disclosure, a semiconductor material of the channel region of the semiconductor layer may be P-type, and semiconductor materials of the source region and the drain region of the semiconductor layer may both be N-type.

In an embodiment of the present disclosure, the semiconductor material of the channel region of the semiconductor layer may be silicon doped with boron; the semiconductor materials of the source region and the drain region of the semiconductor layer may both be silicon doped with boron and phosphorus, and doping concentrations of the phosphorus in the semiconductor materials of the source region and the drain region of the semiconductor layer are both greater than doping concentrations of the boron.

In an embodiment of the present disclosure, lengths of a plurality of word lines arranged along the first direction may be different to form a staircase shape.

In an embodiment of the present disclosure, a material of the word line may be any one or more of polysilicon and polysilicon germanium.

In an embodiment of the present disclosure, the capacitor may include a first electrode, a second electrode, a dielectric layer arranged between the first electrode and the second electrode, and the drain region is connected to the first electrode.

In an embodiment of the present disclosure, the memory cell column may further include an interlayer isolation layer arranged between gates of transistors of two adjacent memory cells in the memory cell column to isolate the gates of the transistors of the two adjacent memory cells.

In an embodiment of the present disclosure, a material of the interlayer isolation layer may be silicon oxide.

In an embodiment of the present disclosure, the transistor may also include a gate dielectric layer arranged between the channel region and the gate.

In an embodiment of the present disclosure, a material of the gate dielectric layer may be selected from one or more of silicon dioxide, hafnium dioxide (HfO₂), alumina (Al₂O₃), zirconia (ZrO).

In an embodiment of the present disclosure, the semiconductor device may further include one or more memory cell isolation posts extending along the first direction, and one of the memory cell isolation posts may be arranged every two memory cell columns in the second direction.

In an embodiment of the present disclosure, a material of the memory cell isolation post may be silicon oxide.

In an embodiment of the present disclosure, the semiconductor device may further include an internal support layer, which is arranged between two adjacent semiconductor layers along the first direction and configured to provide a support to the semiconductor layer.

In an embodiment of the present disclosure, the internal support layer may be located on both sides of the memory cell isolation post.

In an embodiment of the present disclosure, a material of the internal support layer may be silicon nitride (SiN).

An embodiment of the present disclosure also provides a manufacturing method of the semiconductor device, including:
disposing and stacking epitaxial layers composed of a plurality of sacrificial layers and a plurality of initial semiconductor layers along the first direction in the order of the sacrificial layer and the initial semiconductor layer on a side of the substrate, and making a layer farthest from the substrate in the epitaxial layers be a sacrificial layer;
defining a memory cell region in the epitaxial layers and etching a memory cell isolation groove along the first direction, and filling a memory cell isolation post in the memory cell isolation groove;
removing the sacrificial layer in a non-word line region and retaining the sacrificial layer in the word line region; the remaining initial semiconductor layers form a plurality of initial semiconductor layers arranged in an array along the first direction and the third direction and extending along the second direction, and the initial semiconductor layer includes a source region and a drain region located at two ends, and a channel region located between the source region and the drain region in the second direction; changing a polarity of semiconductor materials of the source region and the drain region of the initial semiconductor layer, and keeping a polarity of the channel region of the initial semiconductor layer unchanged by using the sacrificial layer of the word line region as a mask to obtain a semiconductor layer having the source region, the drain region and an inversion channel region; removing the sacrificial layer of the word line region;
arranging a gate surrounding the channel region around the channel region of the semiconductor layer to obtain a plurality of transistors formed by the semiconductor layer and the gate; and there is one semiconductor layer arranged in the third direction, such that the gate on this semiconductor layer serves as a word line; or there are a plurality of semiconductor layers arranged in the third direction, such that the gates on the plurality of semiconductor layers arranged in the third direction are connected together in the third direction to form a word line;
arranging a capacitor, surrounding an end of the drain region, around an end of the drain region, away from the channel region, of the semiconductor layer; and
opening vertical bit line grooves through the semiconductor layer in bit line regions of the plurality of semiconductor layers arranged along the first direction, filling a bit line material in the bit line grooves and between the bit line grooves of the plurality of semiconductor layers arranged along the first direction to form a bit line extending along the first direction, and connecting the bit line with the source regions of the plurality of semiconductor layers in contact with the bit line such that the source regions of the plurality of semiconductor layers share one bit line.

In an embodiment of the present disclosure, the sacrificial layer of the non-word line region is removed and the sacrificial layer of the word line region is retained; the remaining initial semiconductor layers form a plurality of initial semiconductor posts arranged in an array along the first direction and the third direction and extending along the second direction, and the initial semiconductor post includes a source region and a drain region located at two ends, and a channel region located between the source region and the drain region in the second direction; a polarity of semiconductor materials in the source region and the drain region of the initial semiconductor post is changed, and a polarity of the channel region of the initial semiconductor post is kept unchanged by using the sacrificial layer of the word line region as a mask to obtain a semiconductor post having the source region, the drain region and an inversion channel region; removing the sacrificial layer of the word line region may include:
removing the sacrificial layer in the non-word line region and retaining the sacrificial layer in the word line region; the remaining initial semiconductor layers form a plurality of initial semiconductor layers arranged in an array along the first direction and the third direction and extending in the second direction, and the initial semiconductor layer includes a source region and a drain region located at two ends, and a channel region located between the source and drain regions in the second direction;
arranging a doping layer containing a target element around the source region and the drain region of the initial semiconductor layer;
diffusing the target element in the doping layer into the semiconductor materials of the source region and the drain region of the initial semiconductor layer so that the polarity of the semiconductor materials of the source region and the drain region of the initial semiconductor layer changes; and keeping the polarity of the channel region of the initial semiconductor layer unchanged by using the sacrificial layer of the word line region as a mask to obtain a semiconductor layer having the source region, the drain region and an inversion channel region; and removing the doping layer and the sacrificial layer of the word line region.

In an embodiment of the present disclosure, the material of the sacrificial layer may be silicon germanium (SiGe).

In an embodiment of the present disclosure, the semiconductor materials of the source region and the drain region of the initial semiconductor layer may both be P-type, and the semiconductor materials of the source region and the drain region of the semiconductor layer may both be N-type.

In an embodiment of the present disclosure, the target element may be phosphorus, and a material of the doping layer may be selected from any one or more of a phosphorus-containing oxide and a phosphorus-containing nitride.

In an embodiment of the present disclosure, the defining of a memory cell region in the epitaxial layers and the etching of a memory cell isolation groove along the first direction, and the filling of a memory cell isolation post in the memory cell isolation groove may include:
defining a memory cell region in the epitaxial layers and etching a memory cell isolation groove along the first direction;
performing a side etching on a portion of the memory cell isolation groove corresponding to the sacrificial layer along the second direction to obtain an internal support groove, and filling the internal support layer in the internal support groove; and
filling a memory cell isolation post in the memory cell isolation groove.

In an embodiment of the present disclosure, a gate surrounding the channel region is arranged around the channel region of the semiconductor post to obtain a plurality of transistors formed by the semiconductor post and the gate; if there is one semiconductor post arranged in the third direction, the gate on the semiconductor post is used as a word line; or, if there are a plurality of semiconductor posts arranged in the third direction, connecting the gates on the plurality of semiconductor posts arranged in the third direction together in the third direction to form a word line may include:
sequentially arranging a gate dielectric layer and a gate surrounding the channel region around the channel region of the semiconductor layer to obtain a plurality of transistors formed by the semiconductor layer and the gate; and there is one semiconductor layer arranged in the third direction, so that the gate on this semiconductor layer serves as a word line; or there are a plurality of semiconductor layers arranged in the third direction, so that the gates on the plurality of semiconductor layers arranged in the third direction are connected together in the third direction to form a word line.

In an embodiment of the present disclosure, a gate electrode surrounding the channel region is arranged around the channel region of the semiconductor post to obtain a plurality of transistors formed by the semiconductor post and the gate; If there is one semiconductor post arranged in the third direction, the gate on the semiconductor post is used as a word line; or, if there are a plurality of semiconductor posts arranged in the third direction, connecting the gates on the plurality of semiconductor posts arranged in the third direction together in the third direction to form word lines may include setting the plurality of word lines arranged in the first direction to be of different lengths to make the plurality of word lines arranged along the first direction present a staircase shape.

In an embodiment of the present disclosure, a gate surrounding the channel region are arranged around the channel region of the semiconductor post to obtain a plurality of transistors formed by the semiconductor post and the gate; if there is one semiconductor post arranged in the third direction, the gate on the semiconductor post is used as a word line; or, if there are a plurality of semiconductor posts arranged in the third direction, connecting the gates on the plurality of semiconductor posts arranged in the third direction together in the third direction to form a word line may include: arranging an interlayer isolation layer between two adjacent semiconductor layers along the first direction so as to isolate the gates on the two adjacent semiconductor layers along the first direction.

In an embodiment of the present disclosure, the providing of a capacitor around an end of the drain region, away from the channel region, of the semiconductor layer may include: sequentially arranging a first electrode, a dielectric layer and a second electrode around an end of the drain region, away from the channel region, of the semiconductor layer to obtain the capacitor surrounding the drain region of the semiconductor layer.

In an embodiment of the present disclosure, the manufacturing method may further include: opening a vertical bit line groove through the semiconductor post in a bit line region of the plurality of semiconductor posts arranged along the first direction, filling a bit line material in the bit line grooves and between the bit line grooves of the plurality of semiconductor posts arranged along the first direction to form a bit line extending along the first direction, and connecting the bit line with the source region of the plurality of semiconductor posts in contact with the bit line, such that after the source region of the plurality of semiconductor posts share one bit line, an isolation material in a blank space is filled between the semiconductor layer, the bit line and the word line.

An embodiment of the present disclosure also provide a dynamic random access memory (DRAM), including a semiconductor device as described above.

An embodiment of the present disclosure also provides an electronic apparatus, including a dynamic random access memory as described above.

In an embodiment of the present disclosure, the electronic apparatus may include a storage equipment, a smart phone, a computer, a tablet computer, an artificial intelligence apparatus, a wearable apparatus, or a mobile power supply.

Other features and advantages of the present disclosure will be set forth in the following specification, and moreover, partially become more apparent from the specification, or are understood by implementing the present disclosure. Other advantages of the present disclosure may be achieved and obtained by embodiments described in the description and the drawings.

### BRIEF DESCRIPTION OF DRAWINGS

The accompanying drawings are used for providing understanding of technical solutions of the present disclosure, and form a part of the specification. They are used for explaining the technical solutions of the present disclosure together with the embodiments of the present disclosure, but do not form a limitation on the technical solutions of the present disclosure.

FIG. 1A is a schematic front view of a sectional structure of a semiconductor device according to an exemplary embodiment of the present disclosure.

FIG. 1B is a schematic top view of a structure of a semiconductor device according to an exemplary embodiment of the present disclosure.

FIG. 2A is a schematic front view of a sectional structure of a semiconductor device according to another exemplary embodiment of the present disclosure.

FIG. 2B is a schematic top view of a structure of a semiconductor device according to another exemplary embodiment of the present disclosure.

FIG. 3 is a process flow diagram of a manufacturing method according to an embodiment of the present disclosure.

FIG. 4A is a schematic front view of a sectional structure of an intermediate product obtained by an intermediate step of a manufacturing method of a semiconductor device according to an exemplary embodiment of the present disclosure.

FIG. 4B is a schematic top view of a structure of a manufacturing method of a semiconductor device according to an exemplary embodiment of the present disclosure.

FIG. 5A is a schematic front view of a sectional structure of an intermediate product obtained by an intermediate step of a manufacturing method of a semiconductor device according to an exemplary embodiment of the present disclosure.

FIG. 5B is a schematic top view of a structure of an intermediate product obtained by an intermediate step of a manufacturing method of a semiconductor device according to an exemplary embodiment of the present disclosure.

FIG. 6A is a schematic front view of a sectional structure of an intermediate product obtained by an intermediate step of a manufacturing method of a semiconductor device according to an exemplary embodiment of the present disclosure.

FIG. 6B is a schematic top view of a structure of an intermediate product obtained by an intermediate step of a manufacturing method of a semiconductor device according to an exemplary embodiment of the present disclosure.

FIG. 7A is a schematic front view of a sectional structure of an intermediate product obtained by an intermediate step of a manufacturing method of a semiconductor device according to an exemplary embodiment of the present disclosure.

FIG. 7B is a schematic top view of a structure of an intermediate product obtained by an intermediate step of a manufacturing method of a semiconductor device according to an exemplary embodiment of the present disclosure.

FIG. 8A is a schematic front view of a sectional structure of an intermediate product obtained by an intermediate step of a manufacturing method of a semiconductor device according to an exemplary embodiment of the present disclosure.

FIG. 8B is a schematic top view of a structure of an intermediate product obtained by an intermediate step of a manufacturing method of a semiconductor device according to an exemplary embodiment of the present disclosure.

FIG. 9A is a schematic front view of a sectional structure of an intermediate product obtained by an intermediate step of a manufacturing method of a semiconductor device according to an exemplary embodiment of the present disclosure.

FIG. 9B is a schematic top view of a structure of an intermediate product obtained by an intermediate step of a manufacturing method of a semiconductor device according to an exemplary embodiment of the present disclosure.

FIG. 10A is a schematic front view of a sectional structure of an intermediate product obtained by an intermediate step of a manufacturing method of a semiconductor device according to an exemplary embodiment of the present disclosure.

FIG. 10B is a schematic top view of a structure of an intermediate product obtained by an intermediate step of a manufacturing method of a semiconductor device according to an exemplary embodiment of the present disclosure.

The meanings of the symbols in the drawings are:
100—substrate; 200—memory cell column; 300—bit line; 300′—bit line groove; 400—word line; 500—memory cell isolation post; 500′—memory cell isolation groove; 600—internal support layer; 600′—internal support groove; 700—isolation material; 800-sacrificial layer; 1—memory cell; 1′—memory cell region; 10—transistor; 11—semiconductor layer; 11′—initial semiconductor layer; 11′—initial semiconductor post; 111/111′—source region; 112—channel region; 113/113′—drain region; 114—doping layer; 12—gate; 20—capacitor; 21 first electrode; 22 second electrode; 23—dielectric layer; 2—interlayer isolation layer.

### DETAILED DESCRIPTION

To make the objectives, technical solutions, and advantages of the present disclosure clearer, the embodiments of the present disclosure will be described in detail below in combination with the accompany drawings. It should be noted that the following examples of the present disclosure and the features of the examples may be arbitrarily combined with each other provided that there is no conflict.

In the description of the present disclosure, ordinal numerals such as “first” and “second” are set to avoid confusion of constituents, but not intended for restriction in quantity.

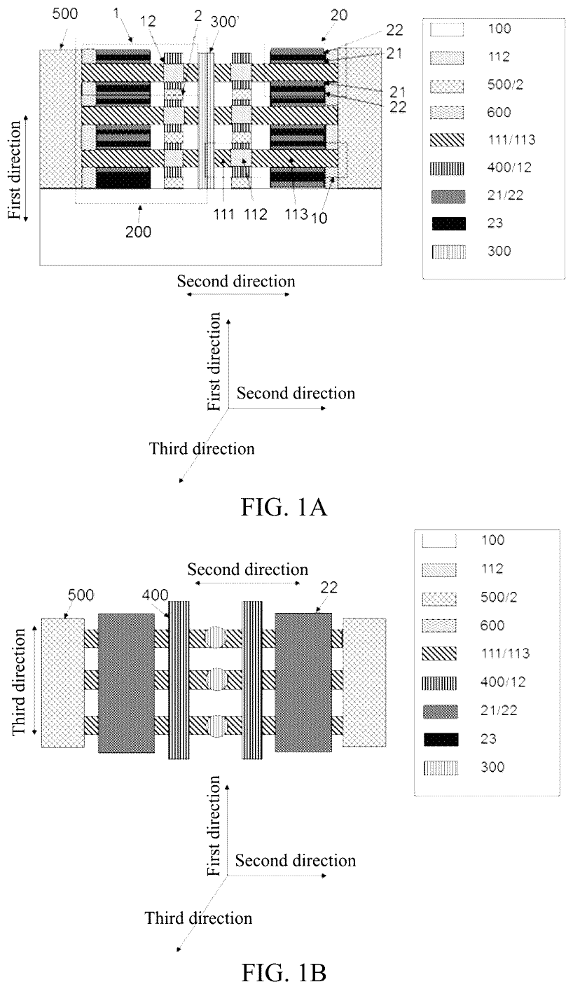

An embodiment of the present disclosure provides semiconductor devices. FIG. 1A is a schematic front view of a sectional structure of a semiconductor device according to an exemplary embodiment of the present disclosure, and FIG. 1B is a schematic top view of a structure of a semiconductor device according to an exemplary embodiment of the present disclosure. As shown in FIG. 1A and FIG. 1B, the semiconductor device may include: a substrate 100, a plurality of memory cell columns 200, a plurality of Bit Lines (BL) 300 extending along a first direction, and a plurality of word lines (WL) 400 extending along a third direction.

Each of the memory cell column 200 includes a plurality of memory cells 1 disposed and stacked along a first direction on a side of the substrate 100, and the plurality of memory cell columns 200 are arranged to be an array on the substrate 100 along a second direction and a third direction; each memory cell 1 includes a transistor 10 and a capacitor 20, wherein the transistor 10 includes a semiconductor layer 11 and a gate 12; the semiconductor layer 11 extends along a second direction having two ends and includes a source region 111, a channel region 112 and a drain region 113, wherein the source region 111 and the drain region 113 are respectively located at the two ends of the semiconductor layer 11, the channel region 112 is located between the source region 111 and the drain region 113, and the gate 12 surrounds the channel region 112; the capacitor 20 surrounds an end of the drain region 113 away from the channel region 112, and the channel region 112 of the semiconductor layer 11 is an inversion channel region.

Source regions 111 of transistors 10 of a plurality of memory cells 1 of two adjacent memory cell columns 200 along the second direction are all connected to one common bit line 300.

The substrate 100 may be provided with one or more memory cell columns 200 in the third direction; when the substrate 100 is provided with one memory cell column 200 in the third direction, each of the word lines 400 is formed by the gate 12 of the transistor 10 of one memory cell 1 of one memory cell column 200 arranged in the third direction; or when the substrate 100 is provided with a plurality of memory cell columns 200 in the third direction, each of the word lines 400 is formed by connecting together the gates 12 of the transistors 10 of the plurality of memory cells 1 arranged in the third direction.

In the description of the present disclosure, the “first direction” is defined as a direction perpendicular to a plane in which the substrate is located, i.e. a direction in which the height of the semiconductor device is located; the “second direction” is defined as a direction perpendicular to the “first direction” and in which the width of the substrate is located; and the “third direction” is defined as a direction perpendicular to the “first direction” and in which the length of the substrate is located. The “first direction”, “second direction” and “third direction” may be shown in FIG. 1A and FIG. 1B.

In the description of the present disclosure, the “inversion channel region 112” means that the polarity of the channel region 112 of the semiconductor layer is different from that of the source region 111 of the semiconductor layer, the polarity of the channel region 112 is different from that of the drain region 113 of the semiconductor layer, the polarities of the source region 111 and the drain region 113 are the same, and the polarity of the channel region 112 may be inverted when the semiconductor device is turned on. For example, the semiconductor material of the channel region 112 of the semiconductor layer may be P-type (also called hole type), and the semiconductor materials of the source region 111 and the drain region 113 of the semiconductor layer may both be N-type (also called electron type). When the semiconductor device is turned on, the polarity of the channel region 112 is reversed from P-type to N-type.

In the description of the present disclosure, each of memory cell columns is formed by a plurality of memory cells disposed and stacked on a side of the substrate along the first direction. The present disclosure takes one or more memory cells belonging to the same layer as one group, the group of memory cells is disposed and stacked in a direction perpendicular to the substrate, and memory cells groups of different stacks constitute columns extending along a direction perpendicular to the substrate.

The plurality of groups constitute one array, that is to say, the groups of the memory cell of each layer constitute one array, or a plurality of columns formed by a plurality of stacked memory cell groups constitute one array. It may also be expressed that a plurality of memory cell columns are arranged along the second direction and the third direction to form an array.

The semiconductor device of an embodiment of the present disclosure arranges the semiconductor layer of the transistor transversely (i.e. extending along the second direction) and arranges the capacitor between the semiconductor layers of adjacent transistors rather than the left and right sides of the transistor, so a plurality of transistors and a plurality of capacitors may be stacked in the first direction to form a memory cell column with a three-dimensional stacked structure, so that more memory cells may be arranged on a limited substrate surface, and the memory density of the semiconductor device is improved; moreover, sources of transistors of a plurality of memory cells in two adjacent memory cell columns in the second direction shares one bit line, which may further reduce a size of the semiconductor device and further increase a memory density of the semiconductor device, thereby reducing a manufacturing cost per unit Gb, and provide a new technology research and development direction for semiconductor devices under the bottleneck of miniaturization; and in addition, the channel of the transistor of the semiconductor device in the embodiment of the present disclosure adopts an inversion channel, and the polarity of the channel may be inverted after the semiconductor device is turned on, which may bring a high on-state current, thus obtaining a high switching ratio.

In an embodiment of the present disclosure, the semiconductor material of the channel region 112 of the semiconductor layer may be silicon doped with boron, and the semiconductor material of the channel region 112 of the semiconductor layer is P-type; the semiconductor materials of the source region 111 and the drain region 113 of the semiconductor layer may both be silicon doped with boron and phosphorus; and in the semiconductor materials of the source region 111 and the drain region 113 of the semiconductor layer, a doping concentration of phosphorus is far greater than a doping concentration of boron, and the semiconductor materials of the source region 111 and the drain region 113 of the semiconductor layer are N-type.

In an embodiment of the present disclosure, the semiconductor layer may be a semiconductor post.

In an embodiment of the present disclosure, one memory cell column may include 2 to 100 memory cells, for example, 2, 3 (as shown in FIG. 1A and FIG. 1B), 4, 5, 10, 13, 15, 18, 20, 30, 40, 50, 60, 70, 80, 90, 100 memory cells.

In an embodiment of the present disclosure, the substrate may be provided with 2 to 1000 memory cell columns in the second direction, for example, 2 (as shown in FIG. 1A and FIG. 1B), 4, 6, 8, 10, 12, 14, 16, 18, 20, 30, 40, 50, 60, 70, 80, 90, 100, 200, 300, 400, 500, 600, 700, 800, 900, 1000 memory cell columns may be provided; and the substrate may be provided with 1 to 100 memory cell columns in the third direction, for example, 1, 2, 3 (as shown in FIGS. 1A and 1B), 4, 5, 12, 14, 16, 18, 20, 30, 40, 50, 60, 70, 80, 90, 100 memory cell columns may be provided.

In an embodiment of the present disclosure, the substrate may be a semiconductor substrate, which may be, for example, a monocrystalline silicon substrate, and may further be a Semiconductor on Insulator (SOI) substrate, such as, a Silicon On Sapphire (SOS) substrate, a Silicon On Glass (SOG) substrate, an epitaxial layer of silicon on a base substrate semiconductor, or other semiconductor or photoelectric material, such as silicon-germanium (Si₁₋ₓGeₓ, wherein x may be, for example, a mole fraction between 0.2 and 0.8), germanium (Ge), gallium arsenide (GaAs), gallium nitride (GaN), or indium phosphide (InP). The substrate may or may not be doped.

In an embodiment of the present disclosure, a semiconductor material of the channel region of the semiconductor layer may be P-type, and semiconductor materials of the source region and the drain region of the semiconductor layer may both be N-type.

In an embodiment of the present disclosure, the semiconductor material of the channel region of the semiconductor layer may be silicon doped with boron; the semiconductor materials of the source region and the drain region of the semiconductor layer may both be silicon doped with boron and phosphorus, and in the semiconductor materials of the source region and the drain region of the semiconductor layer, doping concentrations of the phosphorus are both greater than doping concentrations of the boron.

In an embodiment of the present disclosure, the lengths of the plurality of word lines arranged along the first direction may be different, so that the plurality of word lines arranged along the first direction and located in different layers may form a staircase shape.

In an embodiment of the present disclosure, the material of the word line may be a material compatible with the semiconductor layer, which may include, for example, any one or more of conductive polysilicon, conductive polysilicon germanium, and the like.

In an embodiment of the present disclosure, the material of the bit line may be selected from any one or more of tungsten, molybdenum (Mo), cobalt (Co), and other metal materials having similar properties.

In an embodiment of the present disclosure, as shown in FIG. 1A and FIG. 1B, the capacitor 20 may include a first electrode 21, a second electrode 22, a dielectric layer 23 arranged between the first electrode 21 and the second electrode 22, and the drain region 113 is connected to the first electrode 21. The second electrodes 22 of the plurality of capacitors 20 arranged along the third direction may be connected together, but the first electrodes 21 thereof are separated.

In an embodiment of the present disclosure, as shown in FIG. 1A and FIG. 1B, the first electrode 21 may be an inner electrode plate and the second electrode 22 may be an outer electrode plate.

In an embodiment of the present disclosure, as shown in FIG. 1A and FIG. 1B, one transistor 10 may correspond to one capacitor 20, i.e. the memory cell 1 may be of a 1T1C structure.

In an embodiment of the present disclosure, two adjacent capacitors 20 along the first direction may share one outer electrode plate.

In an embodiment of the present disclosure, the materials of the first electrode 21 and the second electrode 22 may each independently be selected from any one or more of other metal materials having similar properties such as titanium nitride (TiN), titanium aluminum (TiAl), tantalum nitride (TaN), etc.

In an embodiment of the present disclosure, a material of the dielectric layer 23 may be a material with a high dielectric constant (K), which may be selected from, for example, any one or more of hafnium dioxide (HfO)₂), alumina (Al₂O₃), zirconia ZrO and strontium titanate (SrTiO)₃, STO).

In an embodiment of the present disclosure, as shown in FIG. 1A and FIG. 1B, the memory cell column 200 may further include an interlayer isolation layer 22 arranged between gates 12 of transistors 10 of two adjacent memory cells 1 in the memory cell column 200, which isolates the gates 12 of the transistors 10 of the two adjacent memory cells 1.

In an embodiment of the present disclosure, a material of the interlayer isolation layer 2 may be silicon oxide, which may be, for example, SiO₂.

In an embodiment of the present disclosure, the interlayer isolation layer 2 may be an interlayer isolation belt.

In an embodiment of the present disclosure, the transistor 10 may also include a gate dielectric layer (also referred to as a gate insulation layer, not shown in the figures), and the gate dielectric layer is arranged between the channel region 112 and the gate 12.

In an embodiment of the present disclosure, a material of the gate dielectric layer may be selected from any one or more of silicon dioxide, hafnium dioxide (HfO₂), alumina (Al₂O₃), zirconia (ZrO).

In an embodiment of the present disclosure, a thickness of the gate dielectric layer may be set according to actual electrical requirements.

In an embodiment of the present disclosure, a material of the gate 12 may be selected from any one or more of polysilicon and polysilicon germanium.

In an embodiment of the present disclosure, as shown in FIG. 1A and FIG. 1B, the semiconductor device may further include one or more memory cell isolation posts 500 extending along the first direction. For example, one of the memory cell isolation posts 500 may be provided at intervals of two memory cell columns 200 in the second direction.

In an embodiment of the present disclosure, a material of the memory cell isolation post may be silicon oxide, which may be selected from, for example, any one or more of a Spin-On Deposition (SOD) silicon oxide thin film, a High Density Plasma (HDP) silicon oxide thin film, and a High Aspect Ratio Process (HARP) silicon oxide thin film.

In an embodiment of the present disclosure, as shown in FIG. 1A and FIG. 1B, the semiconductor device may further include an internal support layer 600, which is arranged between two adjacent semiconductor layers 11 along the first direction and configured to provide a support to the semiconductor layer 11.

In an embodiment of the present disclosure, as shown in FIG. 1A and FIG. 1B, the internal support layer 600 may also be located on both sides of the memory cell isolation post 500. The semiconductor layer 11 may be firmly supported when the internal support layer 600 is provided on both sides of the memory cell isolation post 500.

In an embodiment of the present disclosure, a material of the internal support layer may be a thin film material having a supporting effect, which may be, for example, silicon nitride (SiN).

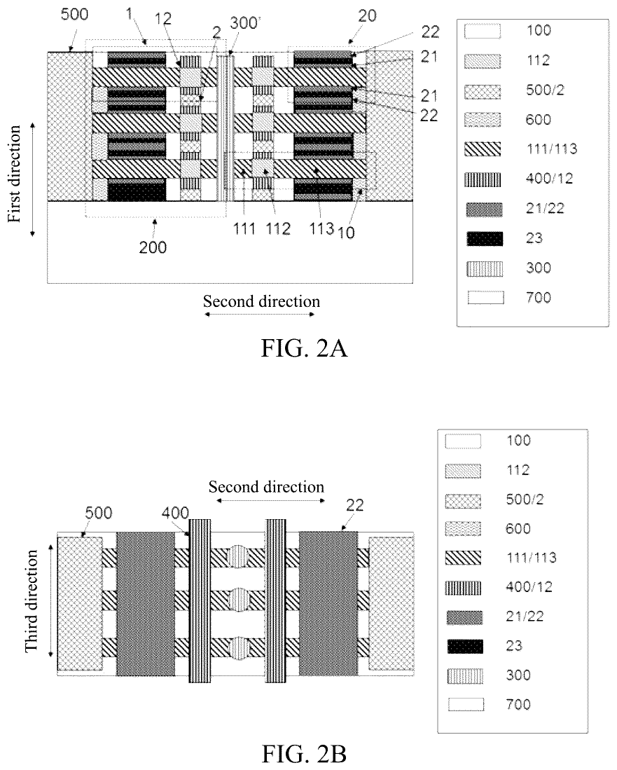

FIG. 2A is a schematic front view of a sectional structure of a semiconductor device according to another exemplary embodiment of the present disclosure, and FIG. 2B is a schematic top view of a structure of a semiconductor device according to another exemplary embodiment of the present disclosure. As shown in FIG. 2A and 2B, in an exemplary embodiment of the present disclosure, an isolation material 700 may be filled in a blank space between the semiconductor layer, the bit line and the word line.

In an embodiment of the present disclosure, the isolation material may be selected from any one or more of a SOD silicon oxide film, an HDP silicon oxide film, and a HARP silicon oxide film.

An embodiment of the present disclosure also provides a manufacturing method of a semiconductor device. As described above, the semiconductor device according to an embodiment of the present disclosure may be obtained by the manufacturing method.

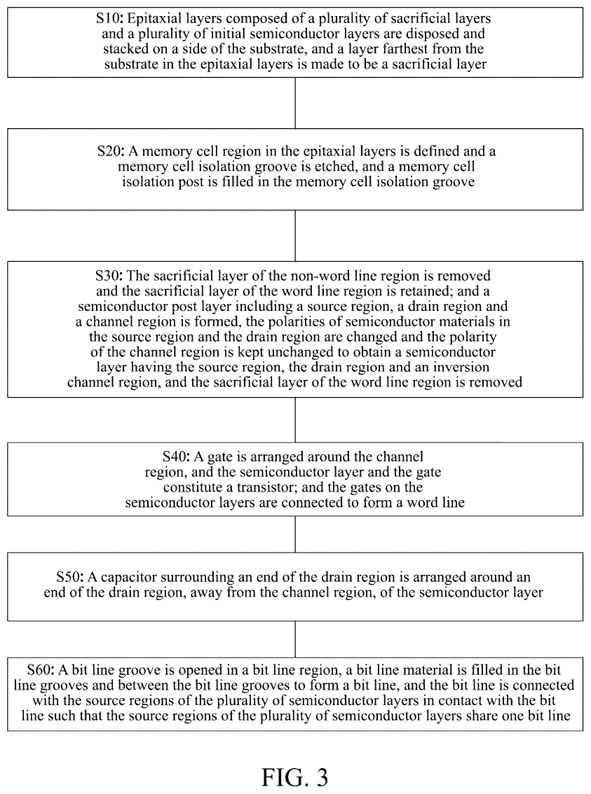

FIG. 3 is a process flow diagram of a manufacturing method according to an embodiment of the present disclosure. As shown in FIG. 3, the manufacturing method may include following acts.

At S10, multiple epitaxial layers are formed, alternating sacrificial layers and initial semiconductor layers on a substrate, and top epitaxial layer is a sacrificial layer.

At S20, a memory cell region in the epitaxial layers is defined and a memory cell isolation groove is etched along the first direction, and a memory cell isolation post is filled in the memory cell isolation groove.

At S30, the sacrificial layer of the non-word line region is removed and the sacrificial layer of the word line region is retained; the remaining initial semiconductor layers form a plurality of initial semiconductor layers arranged in an array along the first direction and the third direction and extending along the second direction, and the initial semiconductor layer includes a source region and a drain region located at two ends, and a channel region located between the source region and the drain region in the second direction; the polarities of semiconductor materials in the source region and the drain region of the initial semiconductor layer are changed, and a polarity of the channel region of the initial semiconductor layer is kept unchanged by using the sacrificial layer of the word line region as a mask, to obtain a semiconductor layer having the source region, the drain region and an inversion channel region; the sacrificial layer of the word line region is removed.

At S40, a gate surrounding the channel region is arranged around the channel region of the semiconductor layer to obtain a plurality of transistors formed by the semiconductor layer and the gate; there is one semiconductor layer arranged in the third direction, and the gate on the semiconductor layer is used as a word line; or there are a plurality of semiconductor layers arranged in the third direction, and the gates on the plurality of semiconductor layers arranged in the third direction are connected together in the third direction to form a word line.

At S50, a capacitor surrounding an end of the drain region is arranged around an end of the drain region, away from the channel region, of the semiconductor layer.

At S60, vertical bit line grooves through the semiconductor layer are opened in bit line regions of the plurality of semiconductor layers arranged along the first direction, the bit line material is filled in the bit line grooves and between the bit line grooves of the plurality of semiconductor layers arranged along the first direction to form a bit line extending along the first direction, and the bit line is connected with the source region of the plurality of semiconductor layers in contact with the bit line, such that the source regions of the plurality of semiconductor layers share one bit line.

In the description of the present disclosure, the “word line region” is defined as a region in the sacrificial layer of the memory cell region where a word line is to be formed, and the “non-word line region” is defined as a region in the sacrificial layer of the memory cell region where a word line is not to be formed.

In an embodiment of the present disclosure, act S30 may include following acts.

At S31, the sacrificial layer in the non-word line region is removed and the sacrificial layer in the word line region is retained; the remaining initial semiconductor layers form a plurality of initial semiconductor layers arranged in an array along the first direction and the third direction and extending in the second direction, and the initial semiconductor layer includes a source region and a drain region located at two ends, and a channel region located between the source and drain regions in the second direction.

At S32, a doping layer containing a target element is arranged around the source region and the drain region of the initial semiconductor layer (here, around the exposed source region and drain region).

At S33, the target element in the doping layer is diffused into the semiconductor materials of the source region and the drain region of the initial semiconductor layer, so that the polarities of the semiconductor materials of the source region and the drain region of the initial semiconductor layer are changed; and the polarity of the channel region of the initial semiconductor layer is kept unchanged by using the sacrificial layer of the word line region as a mask, to obtain a semiconductor layer having the source region, the drain region and an inversion channel region; and the doping layer and the sacrificial layer of the word line region are removed.

In an embodiment of the present disclosure, act S20 may include following acts.

At S21, a memory cell region in the epitaxial layers is defined and a memory cell isolation groove is etched along the first direction.

At S22, a side etching is performed on a portion of the memory cell isolation groove corresponding to the sacrificial layer along the second direction to obtain an internal support groove, and the internal support layer is filled in the internal support groove.

At S23, a memory cell isolation post is filled in the memory cell isolation groove.

In an embodiment of the present disclosure, act S40 may include following acts.

At S41, vertical bit line grooves through the semiconductor layer are opened in bit line regions of the plurality of semiconductor layers arranged along the first direction, the bit line material is filled in the bit line grooves and between the bit line grooves of the plurality of semiconductor layers arranged along the first direction to form a bit line extending along the first direction, and the bit line is connected with the source region of the plurality of semiconductor layers in contact with the bit line, such that the source region of the plurality of semiconductor layers share one bit line.

Optionally, at S42, the plurality of word lines arranged along the first direction are set to be of different lengths such that the plurality of word lines arranged along the first direction and located in different layers present a staircase shape.

Optionally, at S43, an interlayer isolation layer is provided between two adjacent semiconductor layers along the first direction, thereby isolating the gates on the two adjacent semiconductor layers along the first direction.

For example, in an exemplary embodiment of the present disclosure, i) act S40 may include a following act.

At S41, a gate dielectric layer and a gate surrounding the channel region are sequentially arranged around the channel region of the semiconductor layer to obtain a plurality of transistors formed by the semiconductor layer and the gate; there is one semiconductor layer arranged in the third direction, and the gate on the semiconductor layer is used as a word line; or there are a plurality of semiconductor layers arranged in the third direction, and the gates on the plurality of semiconductor layers arranged in the third direction are connected together in the third direction to form a word line.

Alternatively, ii) act S40 may include following acts.

At S41, a gate dielectric layer and a gate surrounding the channel region are sequentially arranged around the channel region of the semiconductor layer to obtain a plurality of transistors formed by the semiconductor layer and the gate; there is one semiconductor layer arranged in the third direction, and the gate on the semiconductor layer is used as a word line; or there are a plurality of semiconductor layers arranged in the third direction, and the gates on the plurality of semiconductor layers arranged in the third direction are connected together in the third direction to form a word line.

At S42, the plurality of word lines arranged along the first direction are set to be of different lengths, such that the plurality of word lines arranged along the first direction and located in different layers present a staircase shape.

Optionally, after the gate on one semiconductor layer is used as a word line or the gates on a plurality of semiconductor layers arranged in the third direction are made to be connected together in the third direction to form a word line, the plurality of word lines arranged in the first direction are set to be of different lengths, such that the plurality of word lines arranged along the first direction present a staircase shape.

Alternatively, iii) act S40 may include following acts.

At S41, a gate dielectric layer and a gate surrounding the channel region are sequentially arranged around the channel region of the semiconductor layer to obtain a plurality of transistors formed by the semiconductor layer and the gate; there is one semiconductor layer arranged in the third direction, and the gate on the semiconductor layer is used as a word line; or there are a plurality of semiconductor layers arranged in the third direction, and the gates on the plurality of semiconductor layers arranged in the third direction are connected together in the third direction to form a word line.

At S43, an interlayer isolation layer is provided between two adjacent semiconductor layers along the first direction, thereby isolating the gates on the two adjacent semiconductor layers along the first direction.

Alternatively, iiii) act S40 may include following acts.

At S41, a gate dielectric layer and a gate surrounding the channel region are sequentially arranged around the channel region of the semiconductor layer to obtain a plurality of transistors formed by the semiconductor layer and the gate; there is one semiconductor layer arranged in the third direction, and the gate on the semiconductor layer is used as a word line; or there are a plurality of semiconductor layers arranged in the third direction, and the gates on the plurality of semiconductor layers arranged in the third direction are connected together in the third direction to form a word line.

At S42, the plurality of word lines arranged along the first direction are set to be of different lengths, such that the plurality of word lines arranged along the first direction and located in different layers present a staircase shape.

Optionally, after the gate on one semiconductor layer is used as a word line or the gates on a plurality of semiconductor layers arranged in the third direction are made to be connected together in the third direction to form a word line, the plurality of word lines arranged in the first direction are set to be of different lengths, such that the plurality of word lines arranged along the first direction present a staircase shape.

At S43, an interlayer isolation layer is provided between two adjacent semiconductor layers along the first direction, thereby isolating the gates on the two adjacent semiconductor layers along the first direction.

In an embodiment of the present disclosure, act S50 may include: sequentially arranging a first electrode, a dielectric layer and a second electrode around an end of the drain region, away from the channel region, of the semiconductor layer, to obtain the capacitor surrounding the drain region of the semiconductor layer.

In an embodiment of the present disclosure, the manufacturing method may further include a following act after act S60.

At S70, an isolation material is filled in a blank space between the semiconductor layer, the bit line, and the word line.

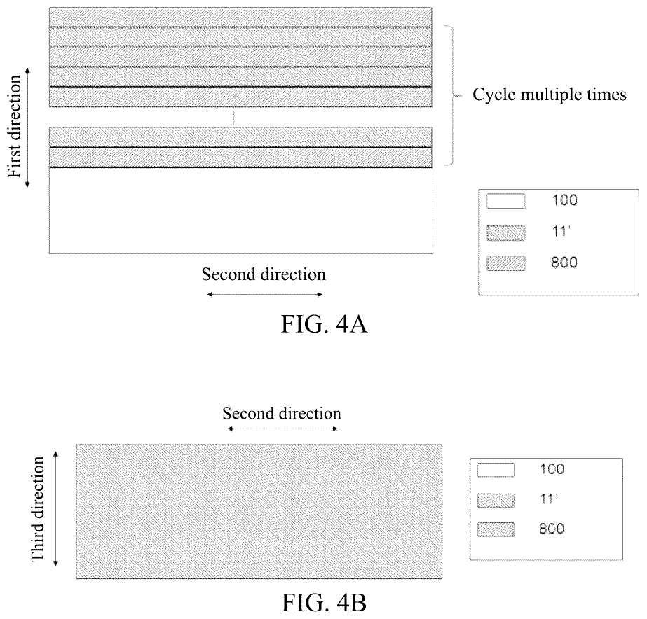

FIG. 4A to FIG. 10B are schematic front views of sectional structures and schematic top views of structures of intermediate products obtained by intermediate steps of a manufacturing method of a semiconductor device according to an exemplary embodiment of the present disclosure. As shown in FIG. 4A to FIG. 10B, in an exemplary embodiment, the manufacturing method of the semiconductor device may include following acts.

At S10, epitaxial layers composed of a plurality of sacrificial layers 800 and a plurality of initial semiconductor layers 11′ are disposed and stacked along the first direction in the order of the sacrificial layer 800 and the initial semiconductor layer 11′ on a side of the substrate 100, and a layer farthest from the substrate in the epitaxial layers is made to be a sacrificial layer, obtaining intermediate products as shown in FIG. 4A and FIG. 4B.

At S21, a memory cell region 1 in the epitaxial layer is defined and a memory cell isolation groove 500 is etched along the first direction.

At S22, a side etching is performed on a portion of the memory cell isolation groove 500′ corresponding to the sacrificial layer 800 along the second direction to obtain an internal support groove 600′, and the internal support layer 600 is filled in the internal support groove 600′.

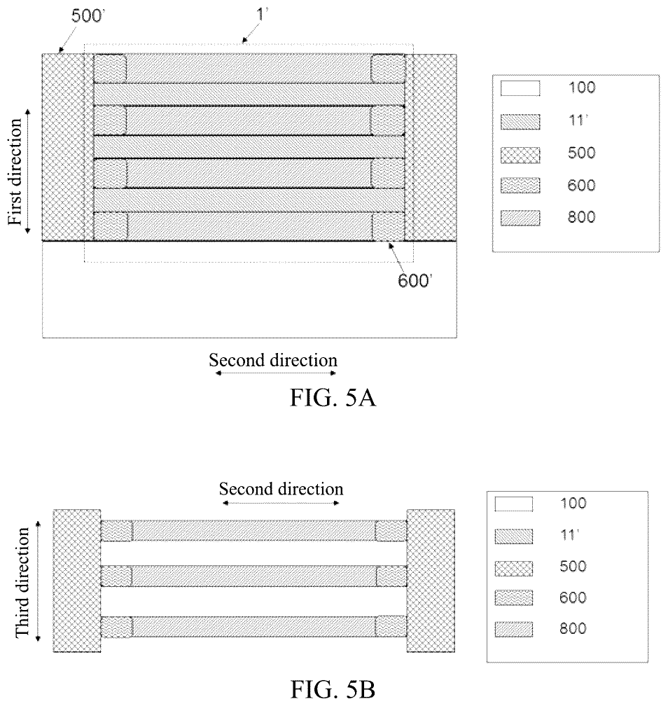

At S23, a memory cell isolation post 500 is filled in the memory cell isolation groove 500′ to obtain intermediate products as shown in FIG. 5A and FIG. 5B.

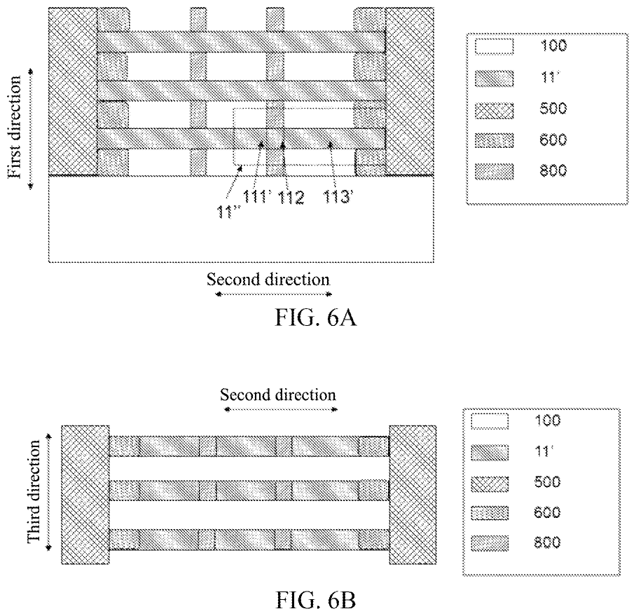

At S31, the sacrificial layers 800 in the non-word line region are removed and the sacrificial layer 800 in the word line region is retained; the remaining initial semiconductor layers 11′ form a plurality of initial semiconductor layers 11″ arranged in an array along the first direction and the third direction and extending in the second direction, and the initial semiconductor layer 11″ includes a source region 111′ and a drain region 113′ located at two ends, and a channel region 112 located between the source and drain regions in the second direction, obtaining intermediate products as shown in FIG. 6A and FIG. 6B.

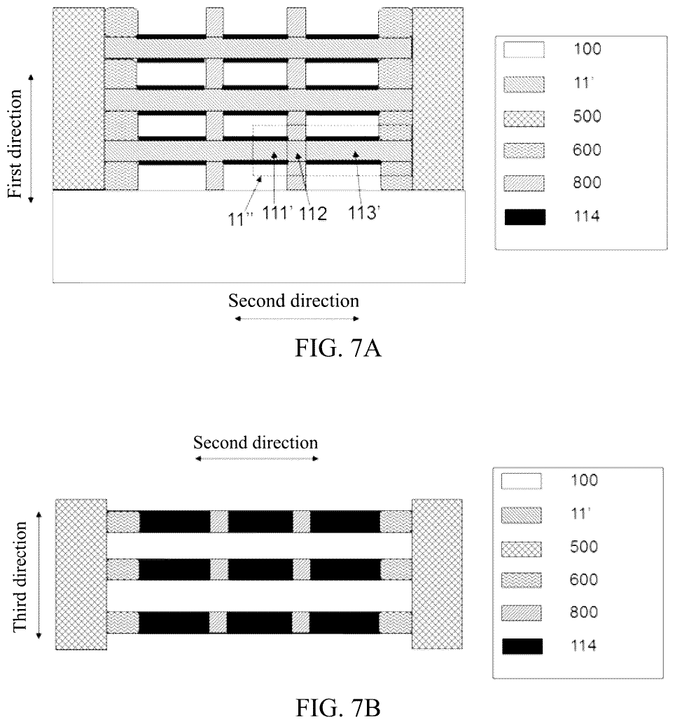

At S32, a doping layer 114 containing a target element is arranged around the exposed source region 111′ and drain region 113′ of the initial semiconductor layer 11″, obtaining intermediate products as shown in FIG. 7A and FIG. 7B.

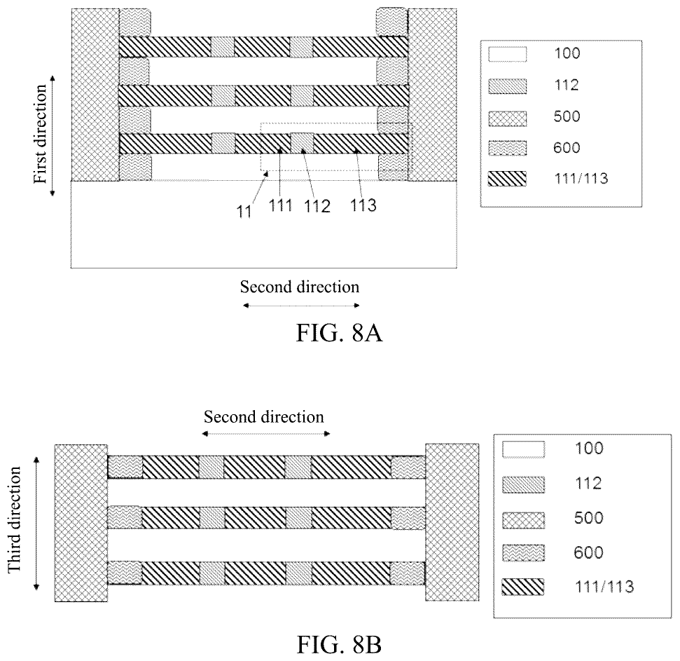

At S33, the target element in the doping layer 114 is diffused into the semiconductor materials of the source region 111′ and the drain region 113′ of the initial semiconductor layer 11′, so that the polarities of the semiconductor materials of the source region 111′ and the drain region 113′ of the initial semiconductor layer 11″ are changed; and the polarity of the channel region 112 of the initial semiconductor layer 11″ is kept unchanged by using the sacrificial layer 800 of the word line region as a mask, to obtain a semiconductor layer 11 having the source region 111, the drain region 113 and an inversion channel region 112; and the doping layer 114 and the sacrificial layer 800 of the word line region are removed, obtaining intermediate products as shown in FIG. 8A and FIG. 8B.

At S41, a gate dielectric layer (not shown in the figures) and a gate 12 surrounding the channel region 112 are sequentially arranged around the channel region 112 of the semiconductor layer 11 to obtain a plurality of transistors 10 formed by the semiconductor layer 11 and the gate 12; and there is one semiconductor layer 11 arranged in the third direction, and the gate 12 on the semiconductor layer 11 is used as a word line 400; or there are a plurality of semiconductor layers 11 arranged in the third direction, and the gates 12 on the plurality of semiconductor posts arranged in the third direction are connected together in the third direction to form a word line 400.

At S42, the plurality of word lines 400 arranged along the first direction are set to be of different lengths, such that the plurality of word lines 400 arranged along the first direction and located in different layers present a staircase shape.

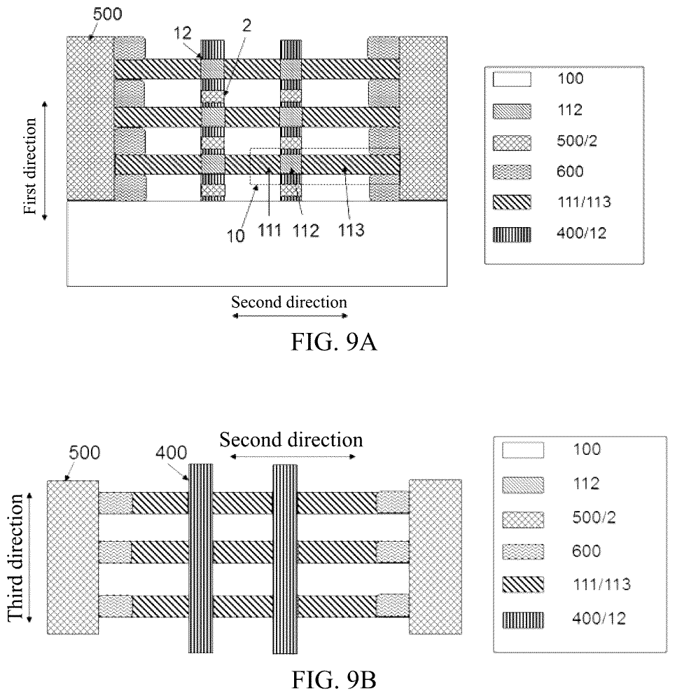

At S43, an interlayer isolation layer 2 is provided between two adjacent semiconductor layers 11 along the first direction, thereby isolating the gates 12 on the two adjacent semiconductor layers 11 along the first direction, obtaining intermediate products as shown in FIG. 9A and FIG. 9B.

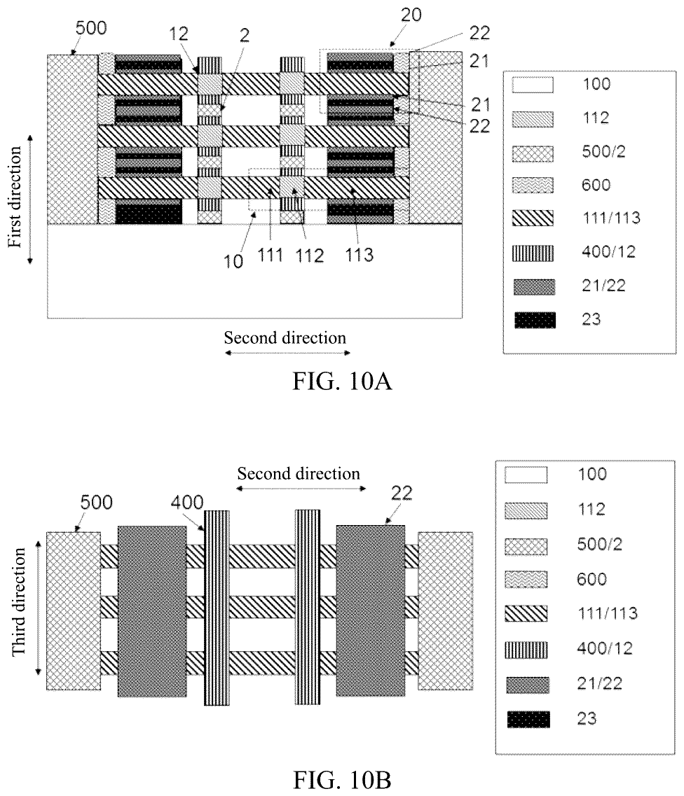

At S50, a first electrode 21, a dielectric layer 23, and a second electrode 22 surrounding the drain region 113 of the semiconductor layer 11 are sequentially arranged around an end of the drain region 113, away from the channel region 112, of the semiconductor layer 11, to obtain a capacitor 20 surrounding the drain region 113 of the semiconductor layer 11, obtaining intermediate products as shown in FIG. 10A and FIG. 10B.

At S60, vertical bit line grooves 300′ through the semiconductor layer 11 are opened in bit line regions of the plurality of semiconductor layers 11 arranged along the first direction, the bit line material is filled in the bit line grooves 300′ and between the bit line grooves 300′ of the plurality of semiconductor layers 11 arranged along the first direction to form a bit line 300 extending along the first direction, and the bit line 300 is connected with the source regions 111 of the plurality of semiconductor layers 11 in contact with the bit line 300, such that the source regions 111 of the plurality of semiconductor layers 11 share one bit line 300, obtaining semiconductor devices as shown in FIG. 1A and FIG. 1B.

At S70, an isolation material 700 is filled in a blank space between the semiconductor layer 11, the bit line 300, and the word line 4000, obtaining semiconductor devices as shown in FIG. 2A and FIG. 2B.

In an embodiment of the present disclosure, a material of the sacrificial layer may be any one or more of other conductive materials having similar properties such as silicon germanium (SiGe).

In an embodiment of the present disclosure, in act S10, a super lattice thin film stack layer of a sacrificial layer/an initial semiconductor layer may be grown on the substrate through an epitaxial apparatus, to obtain a plurality of epitaxial layers composed of the sacrificial layer and the initial semiconductor layer.

In an embodiment of the present disclosure, in act S10, one sacrificial layer and one initial semiconductor layer may be considered as one epitaxial unit, and the epitaxial layer may include a plurality of epitaxial units, for example, 32 epitaxial units.

In an embodiment of the present disclosure, in act S21, a patterning etching may be performed through illumination exposure by using a photo mask in the same layer to form grooves arranged along the third direction and extending along the second direction, which thus isolates a plurality of epitaxial layers formed by the sacrificial layer and the initial semiconductor layer in the third direction, thus obtaining a memory cell region.

In an embodiment of the present disclosure, in act S21, a memory cell isolation groove may be obtained through a Reactive-Ion Etch (RIE).

In an embodiment of the present disclosure, in act S22, a side etching may be performed on a portion of the memory cell isolation groove corresponding to the sacrificial layer through a wet etching.

In an embodiment of the present disclosure, in act S22, the internal support layer may be filled in the internal support layer groove through an Atomic layer deposition (ALD) process or a Chemical Vapor Deposition (CVD) process, for example, SiN may be filled in the internal support layer groove through an ALD process to form the internal support layer.

In an embodiment of the present disclosure, in act S23, a memory cell isolation post may be filled in the memory cell isolation groove through an SOD process, an HDP process or an HARP process, for example, a silicon oxide thin film may be filled in the memory cell isolation groove through an SOD process, an HDP process or an HARP process, thereby forming the memory cell isolation post.

In an embodiment of the present disclosure, in act S31, the sacrificial layers of the non-word line region may be etched away and the sacrificial layers and the initial semiconductor layers of the word line region are retained through an etching method by selecting an etching ratio of the ultra-high sacrificial layer/initial semiconductor layer, and the etching method may be a dry etching or a wet etching.

In an embodiment of the present disclosure, since the sacrificial layers of the word line region is used as a mask to protect the channel region 112 of the initial semiconductor layers in act S30, the material and the polarity of the channel region 112 of the initial semiconductor layer do not change, that is to say, the polarities of the channel region 112 of the initial semiconductor layer, the initial semiconductor layer and the semiconductor layer are the same, so the materials of the channel region 112 of the initial semiconductor layer, the initial semiconductor layer and the semiconductor layer are the same.

In an embodiment of the present disclosure, the semiconductor materials of the source region 111 and the drain region 113 of the initial semiconductor layer may be both P-type, and after the polarity changes in act S30, the source region 111 and the drain region 113 of the initial semiconductor layer are respectively converted into the source region 111 and the drain region 113 of the semiconductor layer, so the semiconductor materials of the source region 111 and the drain region 113 of the semiconductor layer are both N-type.

In order to change the semiconductor materials of the source region 111 and the drain region 113 of the initial semiconductor layer from the P type to the N type, the target element in the doping layer may be diffused into the semiconductor materials of the source region 111 and the drain region 113 of the initial semiconductor layer in act S33, thereby doping the target element into the semiconductor materials of the source region 111 and the drain region 113, and making a doping concentration of the target element greater than a doping concentration of other doping elements in the semiconductor materials of the source region 111 and the drain region 113.

In an embodiment of the present disclosure, the target element may be phosphorus, and the material of the doping layer may be a phosphorus-containing oxide, which may be selected from, for example, any one or more of a phosphorus-containing oxide and a phosphorus-containing nitride.

In an embodiment of the present disclosure, in act S32, one doping layer containing the target element may be deposited on surfaces of the source region 111 and the drain region 113 of the initial semiconductor layer through an ALD process.

In an embodiment of the present disclosure, in act S33, the target element in the doping layer may be diffused into the semiconductor materials of the source region 111 and the drain region 113 of the initial semiconductor layer through a flash anneal.

In an embodiment of the present disclosure, in act S33, an etching ratio of a ultra-high doping layer to the source region and the drain region of the semiconductor layer, and an etching ratio of the sacrificial layer to the source region and the drain region of the semiconductor layer may be sequentially selected through an etching method to sequentially remove the doping layer on the surfaces of the source region and the drain region of the semiconductor layer and the sacrificial layer of the word line region.

In an embodiment of the present disclosure, in act S42, staircase word lines (WL) may be obtained through a trim etch.

In an embodiment of the present disclosure, in act S43, an interlayer isolation layer 2 may be provided through an ALD process or a Chemical Vapor Deposition (CVD) process, and for example, SiO₂ may be filled through an ALD process or a CVD process to form the interlayer isolation layer 2.

In an embodiment of the present disclosure, in act S70, an isolation material may be filled in a blank space through an SOD process, an HDP process or an HARP process, and for example, any one or more of the SOD silicon oxide thin film, the HDP silicon oxide thin film and the HARP silicon oxide thin film may be formed in the blank space through the SOD process, the HDP process or the HARP process.

An embodiment of the present disclosure also provide a dynamic random access memory (DRAM), including a semiconductor device as described above.

An embodiment of the present disclosure also provides an electronic apparatus, including a dynamic random access memory as described above.

In an embodiment of the present disclosure, the electronic apparatus may include a storage equipment, a smart phone, a computer, a tablet computer, an artificial intelligence apparatus, a wearable apparatus, or a mobile power supply.

In the description of the present disclosure, it should be noted that the orientation or positional relationship indicated by the terms “upper”, “lower”, “one side”, “other side”, “an end”, “other end” and the like is based on the orientation or positional relationship shown in the drawings, only for convenience of describing the present disclosure and simplifying the description, and not to indicate or imply that the indicated structure has a specific orientation, is constructed or operates in a specific orientation, and therefore cannot be understood as a limitation of the present disclosure.

In the description of the embodiments of the present disclosure, unless otherwise explicitly specified and defined, the terms “connect” and “arrange” should be understood in a broad sense, for example, a connection may be a fixed connection or a detachable connection, or an integrated connection; and the terms “connect” and “arrange” may be a direct connection, or may be an indirect connection through an intermediary, or may be an internal connection between two elements. For those of ordinary skill in the art, specific meanings of the above terms in the present disclosure may be understood according to specific situations.

Although implementations disclosed in the present disclosure are as described above, the described contents are only implementations used for facilitating understanding of the present disclosure, but are not intended to limit the present disclosure. Without departing from the spirit and scope disclosed in the present disclosure, any person skilled in the art to which the present disclosure belongs may make any modifications and changes in the form and details of implementation, but the protection scope of the present disclosure shall still be defined by the appended claims.

1. A semiconductor device, comprising:
a substrate;
a plurality of memory cell columns, wherein each of the memory cell columns comprises a plurality of memory cells stacked along a first direction on a the substrate, and the plurality of memory cell columns are arranged to form an array on the substrate along a second direction and a third direction; the memory cell comprises a transistor and a capacitor, wherein the transistor comprises a semiconductor layer and a gate; the semiconductor layer extends along the second direction and comprises a source region, a channel region and a drain region, wherein the source region and the drain region are respectively located at two ends of the semiconductor layer, the channel region is located between the source region and the drain region, and the gate surrounds the channel region; the capacitor surrounds an end of the drain region away from the channel region, and the channel region of the semiconductor layer is an inversion channel region;
a plurality of bit lines extending along the first direction, wherein memory cells from two adjacent memory cell columns are all connected to one bit line;
a plurality of word lines extending along the third direction, wherein the substrate is provided with a plurality of memory cell columns in the third direction, and each of the word lines is formed by connecting together gates of transistors of the plurality of memory cells arranged along the third direction.

2. The semiconductor device according to claim 1, wherein a semiconductor material of the channel region of the semiconductor layer is P-type, and semiconductor materials of the source region and the drain region of the semiconductor layer are both N-type.

3. The semiconductor device according to claim 2, wherein the semiconductor material of the channel region of the semiconductor layer is silicon doped with boron; the semiconductor materials of the source region and the drain region of the semiconductor layer are both silicon doped with boron and phosphorus, and in the semiconductor materials of the source region and the drain region of the semiconductor layer, doping concentrations of the phosphorus are both greater than doping concentrations of the boron.

4. The semiconductor device according to claim 1, wherein lengths of a plurality of word lines arranged along the first direction are different and form a staircase shape.

5. The semiconductor device according to claim 4, the word line includes polysilicon, polysilicon germanium, or a combination thereof.

6. The semiconductor device according to claim 1, wherein the capacitor comprises a first electrode, a second electrode, a dielectric layer arranged between the first electrode and the second electrode, and the drain region is connected to the first electrode.

7. The semiconductor device according to claim 1, wherein the memory cell column further comprises an interlayer isolation layer arranged between gates of transistors of two adjacent memory cells in the memory cell column to isolate the gates of the transistors of the two adjacent memory cells, wherein the interlayer isolation layer includes silicon oxide.

8. (canceled)

9. The semiconductor device according to claim 1, wherein the transistor further comprises a gate dielectric layer arranged between the channel region and the gate, wherein the gate dielectric layer includes silicon dioxide, hafnium dioxide, zirconia, alumina, or a combination thereof.

10. (canceled)

11. The semiconductor device according to claim 1, wherein the semiconductor device further comprises one or more memory cell isolation posts extending along the first direction, and one of the memory cell isolation posts is provided every two memory cell columns in the second direction.

12. (canceled)

13. The semiconductor device according to claim 11, wherein the semiconductor device further comprises an internal support layer, which is arranged between two adjacent semiconductor layers along the first direction and configured to provide a support to the semiconductor layer.

14. The semiconductor device according to claim 13, wherein the internal support layer is located on both sides of the memory cell isolation post.

15. (canceled)

16. A manufacturing method of a semiconductor device, comprising:
forming multiple epitaxial layers, alternating sacrificial layers and initial semiconductor layers on a substrate, and top epitaxial layers is a sacrificial layer;
defining a memory cell region in the epitaxial layers and etching a memory cell isolation groove along the first direction, and filling a memory cell isolation post in the memory cell isolation groove;
removing the sacrificial layers in a non-word line region and retaining the sacrificial layers in a word line region; a remaining initial semiconductor layer forming a plurality of initial semiconductor layers arranged in an array along the first direction and a third direction and extending along a second direction, wherein the initial semiconductor layer comprises a source region and a drain region located near two ends, and a channel region located between the source region and the drain region in the second direction; changing polarities of semiconductor materials of the source region and the drain region of the initial semiconductor layer, and keeping a polarity of the channel region of the initial semiconductor layer unchanged by using the sacrificial layer of the word line region as a mask, to obtain a semiconductor layer having the source region, the drain region and an inversion channel region; removing the sacrificial layer of the word line region;
arranging multiple gates, each gate surrounding one channel region, around the channel region of the semiconductor layer to obtain a plurality of transistors formed by the semiconductor layer and the gate; and there is one semiconductor layer arranged in the third direction, such that there are a plurality of semiconductor layers arranged in the third direction, such that the gates on the plurality of semiconductor layers arranged in the third direction are connected together in the third direction to form a word line;
arranging multiple capacitors, each capacitor surrounding an end of one drain region around an end of the drain region, away from the channel region, of the semiconductor layer; and
opening a vertical bit line groove through a plurality of semiconductor layers arranged in the first direction, bit line materials filled in the bit line grooves and between the bit line grooves, forming a bit line extending in the first direction, and the bit line connected with the source regions of the plurality of semiconductor layers, so that the source regions of the plurality of semiconductor layers share one bit line.

17. The manufacturing method according to claim 16, wherein:
removing the sacrificial layer in the non-word line region and retaining the sacrificial layer in the word line region; the remaining initial semiconductor layer forming a plurality of initial semiconductor layers arranged in an array along the first direction and the third direction and extending in the second direction, wherein the initial semiconductor layer comprises a source region and a drain region located at two ends, and a channel region located between the source and drain regions in the second direction;
arranging a doping layer containing a target element around the source region and the drain region of the initial semiconductor layer, wherein the target element is phosphorus, and a material of the doping layer is selected from any one or more of a phosphorus-containing oxide and a phosphorus-containing nitride;
diffusing the target element in the doping layer into the semiconductor materials of the source region and the drain region of the initial semiconductor layer, so that the polarities of the semiconductor materials of the source region and the drain region of the initial semiconductor layer are changed; and keeping the polarity of the channel region of the initial semiconductor layer unchanged by using the sacrificial layer of the word line region as a mask, to obtain the semiconductor layer having the source region, the drain region and the inversion channel region;
and removing the doping layer, and the sacrificial layer of the word line region, wherein a material of the sacrificial layer is silicon germanium, and the semiconductor materials of the source region and the drain region of the initial semiconductor layer are both P-type, and the semiconductor materials of the source region and the drain region of the semiconductor layer are both N-type.

18-20. (canceled)

21. The manufacturing method according to claim 16, wherein the defining the memory cell region in the epitaxial layers, and the etching a memory cell isolation groove along the first direction, and the filling the memory cell isolation post in the memory cell isolation groove comprises:
defining the memory cell region in the epitaxial layers and etching the memory cell isolation groove along the first direction;
performing a side etching on a portion of the memory cell isolation groove corresponding to the sacrificial layer along the second direction to obtain an internal support groove, and filling an internal support layer in the internal support groove; and
filling a memory cell isolation post in the memory cell isolation groove.

22. The manufacturing method according to claim 16, wherein the arranging the gate surrounding the channel region around the channel region of the semiconductor layer to obtain a plurality of transistors formed by the semiconductor layer and the gate; and there is one semiconductor layer arranged in the third direction, such that the gate on this semiconductor layer serves as a word line; or there are a plurality of semiconductor layers arranged in the third direction, such that the gates on the plurality of semiconductor layers arranged in the third direction are connected together in the third direction to form a word line, which comprises:
sequentially arranging a gate dielectric layer and a gate surrounding the channel region around the channel region of the semiconductor layer to obtain a plurality of transistors formed by the semiconductor layer and the gate; and there is one semiconductor layer arranged in the third direction, such that the gate on this semiconductor layer serves as a word line; or there are a plurality of semiconductor layers arranged in the third direction, such that the gates on the plurality of semiconductor layers arranged in the third direction are connected together in the third direction to form a word line.

23. The manufacturing method according to claim 22, wherein the arranging the gate surrounding the channel region around the channel region of the semiconductor layer to obtain a plurality of transistors formed by the semiconductor layer and the gate; and there is one semiconductor layer arranged in the third direction, such that the gate on this semiconductor layer serves as a word line; or there are a plurality of semiconductor layers arranged in the third direction, and the gates on the plurality of semiconductor layers arranged in the third direction are connected together in the third direction to form a word line, which further comprises: setting the plurality of word lines arranged along the first direction to be of different lengths after making the gate on one semiconductor layer be a word line or making the gates on the plurality of semiconductor layers arranged in the third direction be connected together in the third direction to form a word line, such that the plurality of word lines arranged along the first direction present a staircase shape.

24. (canceled)

25. The manufacturing method according to claim 16, wherein the arranging the capacitor around an end of the drain region, away from the channel region, of the semiconductor layer comprises: sequentially arranging a first electrode, a dielectric layer and a second electrode, surrounding the drain region of the semiconductor layer, around an end of the drain region, away from the channel region, of the semiconductor layer to obtain the capacitor surrounding the drain region of the semiconductor layer.

26. The manufacturing method according to claim 16, further comprising: forming a bit line extending in the first direction and connecting the bit line with the source regions of the plurality of semiconductor layers in contact with the bit line, so that the source regions of the plurality of semiconductor layers share one bit line, filling a blank space between the semiconductor layer, the bit line and the word line with an isolation material.

27. A dynamic random access memory, comprising the semiconductor device according to claim 1.

28. An electronic apparatus, comprising a dynamic random access memory according to claim 27.

29. (canceled)
